(19) United States
(12) Patent Application Publication
(10) Pub. No.: US 2026/0208660 A1
(43) Pub. Date: Jul. 23, 2026

(54) MICRO-LED INTELLIGENT HEADLIGHTS FIXTURES FOR THE TRANSPORTATION INDUSTRY

(71) Applicant: VueReal Inc., Waterloo (CA)

(72) Inventors: Gholamreza CHAJI, Waterloo (CA); John CRONIN, Jericho, VT (US)

(73) Assignee: VueReal Inc., Waterloo, ON (CA)

(21) Appl. No.: 19/141,418

(22) PCT Filed: Dec. 21, 2023
(86) PCT No.: PCT/CA2023/051726

§ 371 Date: Jun. 20, 2025

Related U.S. Application Data
(60) Provisional application No. 63/477,056, filed on Dec. 23, 2022.

(51) Int. Cl. B60Q 1/08; B60Q 1/14

(52) U.S. Cl. CPC B60Q 1/08; B60Q 1/143; B60Q 2300/42; B60Q 2300/45

(57) ABSTRACT

The present disclosure provides an intelligent micro-LED headlight fixture that includes a micro-LED panel comprised of a plurality of micro-LEDs, a substrate, a plurality of connectors, and sensors in which the sensors collect data about a vehicle's surroundings. The intelligent micro-LED headlight determines if there is an object. If there is an object, the intelligent micro-LED headlight determines if the object is a road marker, sign marker, road reflector, black ice, or oncoming traffic, compares the identified object to a rules database, extracts the corresponding rule, and adjusts, changes, or alters the light produced by the intelligent micro-LED headlight to improve the driver's visibility.

### BACKGROUND AND FIELD OF THE DISCLOSURE

The present disclosure is generally related to micro-LED intelligent headlight fixtures.

The transportation industry is any industry, business, or establishment operated to convey persons or property from one place to another, whether by rail, highway, air, or water, and all operations and services in connection in addition to that; and also includes storing or warehousing of goods or property, and the repairing, parking, rental, maintenance, or cleaning of vehicles. Vehicle headlights or headlamps illuminate the vehicle's path at night or during dark conditions.

Also, headlights are not smart devices that can alter the light produced by the headlight to improve the driver's vision of surrounding objects. There is a need to improve the function of the headlights to improve the driver's ability to recognize and identify various signage such as road markers, sign markers, road reflectors, lanes, etc.

Lastly, there is a need to improve the function of the headlights to improve the driver's safety by providing better illumination techniques and applications depending on certain situations and the driver's current surroundings.

Thus, there is a need in the prior art to provide micro-LED intelligent headlight fixtures.

### SUMMARY

The present invention relates to a method of improving a driving visibility, the method comprising, having an intelligent micro-LED headlight comprising a micro-LED panel comprised of a plurality of micro-LEDs, a substrate to which the micro-LED tile is bound, a connector which allows electronics of the micro-LED panel to integrate with a vehicle and a plurality of sensors, wherein, the sensors collect data of a vehicle's surroundings, the intelligent micro-LED headlight determines if there is an object, if there is an object, the intelligent micro-LED headlight determines if the object is a road marker, sign marker, road reflector, black ice or oncoming traffic, and compares the identified object to a rules database, extracts the corresponding rule, and adjusts, changes, or alters a light produced by the intelligent micro-LED headlight to improve the driving visibility.

### DESCRIPTIONS OF THE DRAWINGS

FIG. 1: Illustrates integrating a transferred micro-device with an electro-optical thin film device in a hybrid structure, according to an embodiment.

FIG. 2: Illustrates micro-LEDs in a headlight to enhance road markers, according to an embodiment.

FIG. 3: Illustrates using micro-LEDs in a headlight to enhance sign markers, according to

FIG. 4: Illustrates using micro-LEDs in a headlight to enhance road reflectors, according to an embodiment.

FIG. 5: Illustrates using micro-LEDs in a headlight to enhance detecting black ice, according to an embodiment.

FIG. 6: Illustrates using micro-LEDs in a headlight to enhance the interaction with oncoming traffic, according to an embodiment.

### DETAILED DESCRIPTION

Embodiments of the present disclosure will be described more fully hereinafter with reference to the accompanying drawings in which like numerals represent like elements throughout the several figures, and in which example embodiments are shown. Embodiments of the claims may, however, be embodied in many different forms and should not be construed as limited to the embodiments set forth herein. The examples set forth herein are non-limiting examples and are merely examples among other possible examples. The present invention relates to a structure, system and a method wherein plurality of sensors collect date to deliver and intelligent lightning and illumination aspects of a vehicle lightning as necessary.

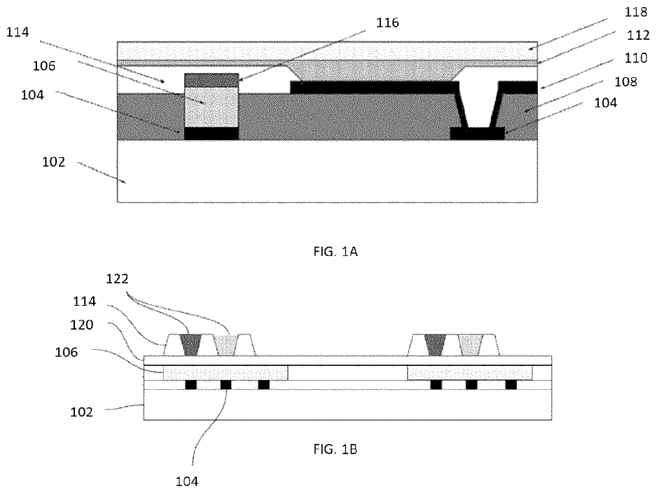

FIG. 1A shows an example of integrating a transferred micro-device 106 with an electro-optical thin film device 112 in a hybrid structure. This is an example of an integrated micro-led tile that is later picked and placed into an array of tiles. It should be obvious to those in the art there are many ways to create micro-led tiles and integrate them in an array of tiles, as per US20160218143A1—Microdevice integration into system substrate. A receiver substrate 102 and contact pads 104 upon which the microdevice 106 arrays are transferred and into which the thin film electro-optical device is integrated in a number of hybrid structure embodiments. Microdevice 106 may be transferred and bonded to the bonding pad 104 of the receiver substrate 100. In one case, a dielectric layer 108 is formed over the substrate 102 to cover the exposed electrodes and conductive layers. Lithography and etching may be used to pattern the dielectric layer 108. Conductive layer 110 is then deposited and patterned to form the bottom electrode of the thin film electro-optical device 112. If there is no risk of unwanted coupling between bottom electrode 110 and other conductive layers in the receiver substrate, the dielectric layer 108 may be eliminated. However, this dielectric layer can also act as a planarization layer to offer better fabrication of electro-optical devices 112. A bank layer 114 is deposited on the substrate 102 to cover the edges of the electrode 110 and the microdevice 106. Thin film electro-optical device 112 is then formed over this structure. Organic LED (OLED) devices are an example of a thin film electro-optical device that may be formed using different techniques such as but not limited to shadow mask, lithography, and printing patterning. Finally, the top electrode 118 of the electro-optical thin film device 112 is deposited and patterned if needed. In an embodiment where the microdevices'106 thickness is significantly high, cracks or other structural problems may occur within the bottom electrode 110. In these embodiments, a planarization layer may be used in conjunction with or without the dielectric layer 108 to address this issue. In another embodiment, the microdevice 106 can have a device electrode 116. This electrode can be common between other microdevices 106 in the system substrate. In this case, the planarization layer (if present) and/or bank structure 114 covers the electrode 116 to avoid any shorts between the electro-optical device 112 and device electrode 116.

FIG. 1B illustrates structures where the device is shared between a few pixels (or sub-pixels) after post-processing to deposit a common electrode and color conversion layers. Here the microdevice 106 is not fully patterned, but the horizontal condition is engineered so that the contacts 104 define the area allocated to each pixel. The system substrate 102 with contact pads 104 and a donor substrate with microdevices 106. After the microdevices 106 are transferred to system substrate 102, one can do post-processing, such as depositing common electrode 120, color conversion layers 122, color filters, and so on. However, the methods described in this disclosure and other possible methods can be used. It is possible to add the color conversion layers as described into pixel (or sub-pixel) active areas after forming the active area. This can offer a higher fill factor and higher performance and avoid color leaking from the side pixel (or sub-pixel) if the active area of the pixel (or sub-pixel) is covered by reflective layers. The microdevices 106 are grown on a buffer/sacrificial layer in another embodiment.

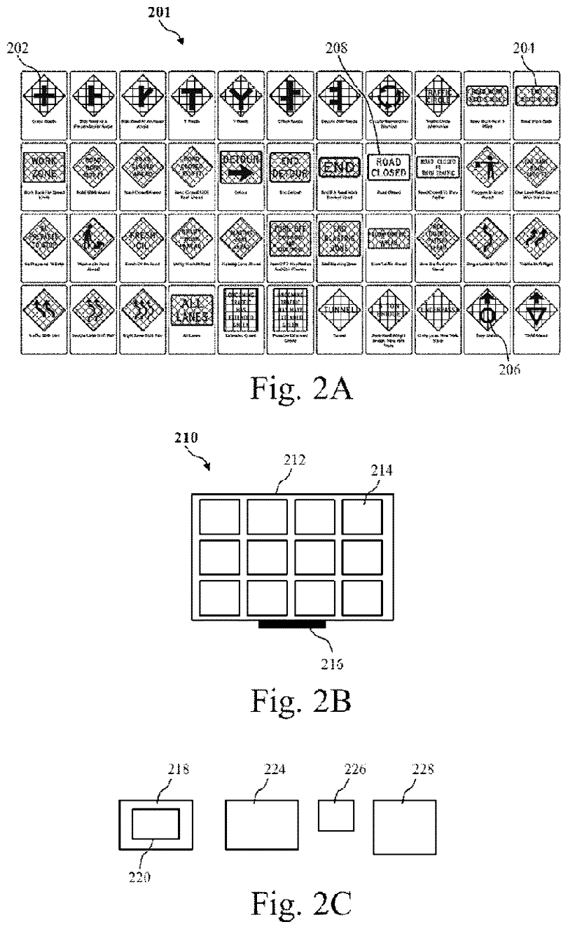

FIG. 2 illustrates an embodiment of using micro-LEDs in a headlight to enhance road markers. FIG. 2A displays a plurality of road markers that may be enhanced by using micro-LEDs in a headlight. Road markers 201 may be traffic signs or road signs erected at the side of or above roads to give instructions or provide information to road users. A road marker 201 may be a regulatory sign which is used to indicate or reinforce traffic laws, regulations, or requirements that apply either at all times or at specified times or places upon a street or highway, the disregard of which may constitute a violation or a sign in general that regulates public behavior in places open to the public. A road marker 201 may be a warning sign is a type of sign which indicates a potential hazard, obstacle, or condition requiring special attention. Some traffic signs indicate road hazards that may not be readily apparent to a driver. Road markers 201 may be reflective through glass beads, micro prisms, or encapsulated lenses that may be present on reflective sheeting. These materials bend light, so it returns to the source, making road signs highly visible at night to drivers with their headlights on. The orange and black 202 road markers 201 may be detected by the rotating color module 220 and be displayed to the driver in an orange light produced by the micro-LED panel 210 to brighten the effects of the orange and black 202 road marker 201. In some embodiments, the light produced by the micro-LED panel 220 may be white light to reflect back the orange and black sign to the driver. In some embodiments, the orange and black 202 road marker 201 may contain glass beads, micro prisms, or encapsulated lenses on reflective sheeting to bend light to return to the highly visible source. The deep orange and black 204 road markers 201 may be detected by the rotating color module 220 and be displayed to the driver in a deep orange light produced by the micro-LED panel 210 to brighten the effects of the deep orange and black 204 road marker 201. In some embodiments, the light produced by the micro-LED panel 220 may be white light to reflect back the deep orange and black sign to the driver. In some embodiments, the deep orange and black 204 road marker 201 may contain glass beads, micro prisms, or encapsulated lenses on reflective sheeting to bend light to comes back to the source highly visible. The orange, red and black 206 road markers 201 may be detected by the rotating color module 220 and be displayed to the driver in an orange and red light produced by the micro-LED panel 210 to brighten the effects of the orange, red and black 206 road marker 201. In some embodiments, the light produced by the micro-LED panel 220 may be white light to reflect back the orange, red and black sign to the driver. In some embodiments, the orange, red and black 206 road marker 201 may contain glass beads, micro prisms, or encapsulated lenses on reflective sheeting to bend light to comes back to the source highly visible. The white and black 208 road markers 201 may be detected by the rotating color module 220 and be displayed to the driver in a white light produced by the micro-LED panel 210 to brighten the effects of the white and black 208 road marker 201. In some embodiments, the light produced by the micro-LED panel 220 may be a plurality of light colors, such as reds, blues, greens, etc., to reflect back the white and black sign to the driver. In some embodiments, the white and black 208 road marker 201 may contain glass beads, micro prisms, or encapsulated lenses on reflective sheeting to bend light to comes back to the source highly visible. FIG. 2B displays an embodiment of the micro-LED panel 210, which produces a plurality of colors to illuminate the road markers 201. The micro-LED panel 210 may be comprised of one or more tiles that contain multiple micro-LEDs. Multiple small micro-LED tiles can be integrated together into a larger flat plate. The micro-LED panel 210 may include a substrate 212, micro-LED unit 214, and a plurality of connectors 216. The micro-LED panel 210 allows for a micro-LED unit 214 to produce visual effects for a driver to act as a headlight or replace a vehicle's existing headlight, such as illuminating a driver's path while driving at night or during dark conditions. In some embodiments, the micro-LED unit 214 may be connected, bonded, adhered, etc., to a vehicle's headlight to produce light or illuminate the vehicle's path. The substrate 212 may be made of glass, silicon, plastics, or any other commonly used material. The substrate 212 may also have active electronic components such as but not limited to transistors, resistors, capacitors, or any other electronic component commonly used in a system substrate. In some cases, the substrate 212 may be a substrate 212 with electrical signal rows and columns. In one example, the substrate 212 may be a sapphire substrate with LED layers grown monolithically on top of it, and the substrate 212 may be a backplane with circuitry to derive micro-LED devices. In some embodiments, the substrate 212 may be a flexible or rigid substrate 212. The micro-LED unit 214 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit 214 may be produced in a plurality of sizes to increase the width or length of the micro-LED unit 214. The connectors 216 may be an electrochemical device used to create an electrical connection between the plurality of micro-LED tiles, which create the micro-LED unit 214. The connectors 216 may receive power, data signals, informational instructions, etc., from the ribbon connector to power and control the individual micro-LEDs in the micro-LED tiles that make up the micro-LED unit 214. FIG. 2C displays the components of the micro-LED headlight to produce the plurality of colors to illuminate the road markers 201. The components may include a memory 218, a rotating color module 220, a processor 224, a bus controller 226, and a micro-LED panel 228. The memory 218 may include, but is not limited to, fixed (hard) drives, magnetic tape, floppy diskettes, optical disks, Compact Disc Read-Only Memories (CD-ROMs), magneto-optical disks, semiconductor memories, such as ROMs, Random Access Memories (RAMs), Programmable Read-Only Memories (PROMs), Erasable PROMs (EPROMs), Electrically Erasable PROMs (EEPROMs), flash memory, magnetic or optical cards, or another type of media/machine-readable medium suitable for storing electronic instructions. The memory 218 may comprise modules implemented as a program. The rotating color module 220 may include the executable program to produce the appropriate lighting conditions to brighten the road markers 201 using the micro-LED panel 228 by collecting data from a plurality of sensors, such as charge-coupled device (CCD) camera, multispectral camera, laser, infrared sensor, radar sensor, etc. that have downstream processing to identify road markers 201 in the path or in front of the vehicle. In some embodiments, the rotating color module 220 may use image recognition to identify the road markers 201. The rotating color module 220 continuously receives data from the sensors and determines if an object is a road marker 201. If it is determined that the object is a road marker 201, the rotating color module compares the road marker 201 to a rules database. The rules database may contain a plurality of road markers 201 and a corresponding executable program that would be sent to the bus controller 226 to send the signal to the micro-LED panel 228 to produce a specific light to brighten the road marker 201. The rotating color module 220 extracts the corresponding rule, or executable program. It executes the program by sending the appropriate signals to the bus controller 226 to illuminate the micro-LED panel 228 in the appropriate lighting, such as if an orange and black 202 road marker 201 is identified, then the extracted rule would be for the micro-LED panel 228 to produce an orange light to brighten the road marker 201. The processor 224 may be configured to decode and execute any instructions received from one or more other electronic devices or server(s). The processor 224 may include one or more general-purpose processors (e.g., INTEL® or Advanced Micro Devices® (AMD) microprocessors) and/or one or more special purpose processors (e.g., digital signal processors or Xilinx® System On Chip (SOC) Field Programmable Gate Array (FPGA) processor). The processor 224 may be configured to execute one or more computer-readable program instructions, such as program instructions, to carry out any of the functions described in this description. The bus controller 226 may be a computer bus used by the vehicle CPU to communicate with devices contained within the computer through physical connections such as cables or printed circuits. The vehicle CPU transmits various control signals to components and devices to transmit control signals to the CPU using the control bus. One of the main objectives of a bus is to minimize the lines needed for communication. The bus controller 226 may be bidirectional and assists the CPU in synchronizing control signals to internal devices and external components. It comprises interrupt lines, byte enables lines, read/write signals, and status lines. The road markers 201 may be enhanced by using a micro-LED panel 228 through the rotating color module 220. The rotating color module 220 begins by continuously polling to receive sensor data from the sensors. For example, the sensors may be a charge-coupled device (CCD) camera, multispectral camera, laser, infrared sensor, radar sensor, etc., that have downstream processing to identify road markers 201 in the path or in front of the vehicle. In some embodiments, the rotating color module 220 may use image recognition to identify the road markers 201. The rotating color module 220 receives the sensor data from the sensors. For example, the sensors may be a charge-coupled device (CCD) camera, multispectral camera, laser, infrared sensor, radar sensor, etc., that have downstream processing to identify road markers 201 in the path or in front of the vehicle. In some embodiments, the rotating color module 220 may use image recognition to identify the road markers 201. The rotating color module 220 determines if there is an object through the collected sensor data. For example, if an object is identified through the sensor data, the rotating color module may determine if the object is a road marker 201. If it is determined that there is no object, the process returns to collecting sensor data. The rotating color module 220 determines if the object is a road marker 201. For example, the rotating color module 220 may compare the identified object to a road marker database which contains the various shapes, colors, etc., of the road markers 201 to allow the rotating color module 220 to identify the object as a road marker through the shape of the object. If the object is a road marker, the rotating color module 220 compares the road marker 201 to a rules database. The rules database may contain a plurality of road markers 201 and a corresponding rule or executable program that would be sent to the bus controller 226 to send the signal to the micro-LED panel 228 to produce a specific light to brighten the road marker 201. For example, if the road marker 201 identified was an orange and black 202 road marker 201, the corresponding rule or executable program may be for the micro-LED panel 228 to produce an orange light to brighten the effects of the orange and black 202 road marker 201. For example, since the road marker 201 is orange and black 202, the orange light produced by the micro-LED panel 228 would reflect back the orange color of the road marker 201, and the black portion of the road marker 201 would be absorbed by the road marker 201 displaying the road marker 201 as a bright orange and black 202 road marker 201. In some embodiments, the light produced by the micro-LED panel 228 may be a slightly altered light that contains more wavelengths for the color of the road marker 201 that is detected. For example, light is made up of wavelengths of light, and each wavelength is a particular color. For example, if the road marker 201 is orange and black 202, the light produced by the micro-LED panel may be white, such as containing all wavelengths, with additional wavelengths that produce an orange color. In some embodiments, the corresponding wavelength may be flashed or flickered on and off to still give the appearance of a white headlight to the naked eye but produces a brighter sign to the driver since there are more corresponding wavelengths of the color of the road marker 201. The rotating color module 220 extracts the corresponding rule from the rules database. For example, the rules database may contain a plurality of road markers 201 and a corresponding executable program that would be sent to the bus controller 226 to send the signal to the micro-LED panel 228 to produce a specific light to brighten the road marker 201. The rotating color module 220 executes the extracted rule from the rules database. For example, the rotating color module 220 extracts the corresponding rule, or executable program. It executes the program by sending the appropriate signals to the bus controller 226 to illuminate the micro-LED panel 228 in the appropriate lighting, such as if an orange and black 202 road marker 201 is identified, then the extracted rule would be for the micro-LED panel 228 to produce an orange light to brighten the road marker 201.

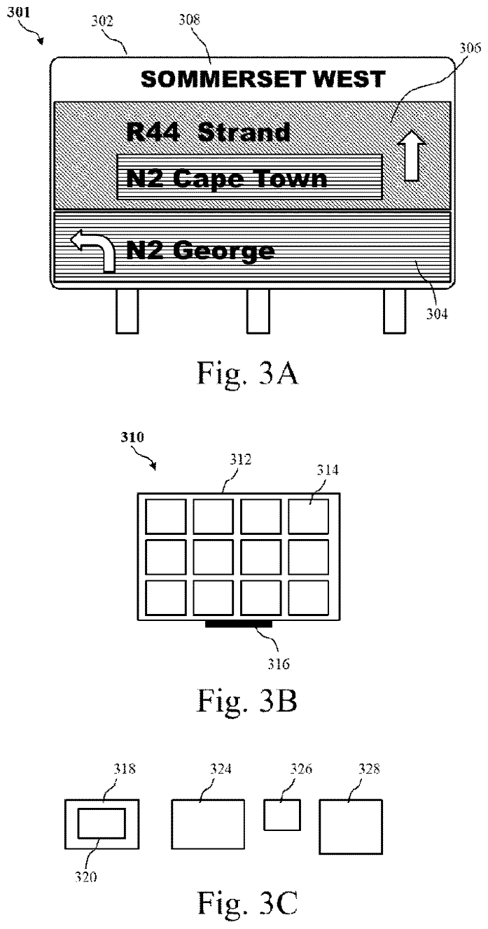

FIG. 3 illustrates an embodiment of using micro-LEDs in a headlight to enhance sign markers. FIG. 3A displays a plurality of sign markers that may be enhanced by using micro-LEDs in a headlight. Sign markers 301 may be traffic signs or road signs are signs erected at the side of or above roads to give instructions or provide information to road users. A sign marker 301 may be an information sign indicator of a source of information or may be informatory. A sign marker 301 may be a direction sign, more fully defined as a direction, position, or indication sign such as any road sign used primarily to give information about the location of either the driver or possible destinations, and is considered a subset of the informative signs group. A road sign 302, which may be a sign marker 301, may be a traffic sign or road sign erected at the side of or above roads to give instructions or provide information to road users. A road sign 302 may be an information sign that is an indicator of a source of information or may itself be informatory. A road sign 302 may be a direction sign, more fully defined as a direction, position, or indication sign, such as any road sign used primarily to give information about the location of either the driver or possible destinations, and is considered a subset of the informative signs group. Region 1 304 may be a section of a road sign 302 that indicates directions for a town, city, village, county, state, road, route, highway, etc. In some embodiments, region 1 304 may provide a direction, position, information, or indication of a location or destination. Region 2 306 may be a section of a road sign 302, which indicates directions for a town, city, village, county, state, road, route, highway, etc. In some embodiments, region 2 306 may provide a direction, position, information, or indication of a location or destination. Region 3 308 may be a section of a road sign 302 which provides an indication of directions for a town, city, village, county, state, road, route, highway, etc. In some embodiments, region 3 308 may provide a direction, position, information, or indication of a location or destination. FIG. 3B displays the components of the micro-LED headlight to produce the plurality of colors to illuminate the sign markers 301. The components may include a micro-LED panel 310, substrate 312, micro-LED unit 314, and connectors 316. The micro-LED panel 310 produces a plurality of colors to illuminate the sign markers 301. The micro-LED panel 310 may be comprised of one or more tiles that contain multiple micro-LEDs. Multiple small micro-LED tiles can be integrated together into a larger flat plate. The micro-LED panel 310 may include a substrate 312, micro-LED unit 314, and a plurality of connectors 316. The micro-LED panel 310 allows for a micro-LED unit 314 that can produce visual effects for a driver to act as a headlight or replace a vehicle's existing headlight, such as illuminating a driver's path while driving at night or during dark conditions. In some embodiments, the micro-LED unit 314 may be connected, bonded, adhered, etc., to a vehicle's headlight to produce light or illuminate the vehicle's path. The substrate 312 may be made of glass, silicon, plastics, or any other commonly used material. The substrate 312 may also have active electronic components such as but not limited to transistors, resistors, capacitors, or any other electronic component commonly used in a system substrate. In some cases, the substrate 312 may be a substrate 312 with electrical signal rows and columns. In one example, the substrate 312 may be a sapphire substrate with LED layers grown monolithically on top of it, and the substrate 312 may be a backplane with circuitry to derive micro-LED devices. In some embodiments, the substrate 312 may be a flexible or rigid substrate 312. The micro-LED unit 314 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit 314 may be produced in a plurality of sizes to increase the width or length of the micro-LED unit 314. The connectors 316 may be an electrochemical device used to create an electrical connection between the plurality of micro-LED tiles, which create the micro-LED unit 314. The connectors 316 may receive power, data signals, informational instructions, etc., from the ribbon connector to power and control the individual micro-LEDs in the micro-LED tiles that make up the micro-LED unit 314. FIG. 3C displays the components of the micro-LED headlight to produce the plurality of colors to illuminate the sign markers 301. The components may include a memory 318, a rotating color module 320, a processor 324, a bus controller 326, and a micro-LED panel 328. The memory 318 may include, but is not limited to, fixed (hard) drives, magnetic tape, floppy diskettes, optical disks, Compact Disc Read-Only Memories (CD-ROMs), and magneto-optical disks, semiconductor memories, such as ROMs, Random Access Memories (RAMs), Programmable Read-Only Memories (PROMs), Erasable PROMs (EPROMs), Electrically Erasable PROMs (EEPROMs), flash memory, magnetic or optical cards, or another type of media/machine-readable medium suitable for storing electronic instructions. The memory 318 may comprise modules implemented as a program. The rotating color module 320 may include the executable program to produce the appropriate lighting conditions to brighten the sign markers 301 using the micro-LED panel 328 by collecting data from a plurality of sensors, such as charge-coupled device (CCD) camera, multispectral camera, laser, infrared sensor, radar sensor, etc. that have downstream processing to identify sign markers 301 in the path or in front of the vehicle. In some embodiments, the rotating color module 320 may use image recognition to identify the sign markers 301. The rotating color module 320 continuously receives data from the sensors and determines if an object is a sign marker 301. If it is determined that the object is a sign marker 301, the rotating color module compares the sign marker 301 to a rules database. The rules database may contain a plurality of sign markers 301 and a corresponding executable program that would be sent to the bus controller 326 to send the signal to the micro-LED panel 328 to produce a specific light to brighten the sign marker 301. The rotating color module 320 extracts the corresponding rule, or executable program, and executes the program by sending the appropriate signals to the bus controller 326 to illuminate the micro-LED panel 328 in the appropriate lighting. The processor 324 may be configured to decode and execute any instructions received from one or more other electronic devices or server(s). The processor 324 may include one or more general-purpose processors (e.g., INTEL® or Advanced Micro Devices® (AMD) microprocessors) and/or one or more special purpose processors (e.g., digital signal processors or Xilinx® System On Chip (SOC) Field Programmable Gate Array (FPGA) processor). The processor 324 may be configured to execute one or more computer-readable program instructions, such as program instructions, to carry out any of the functions described in this description. The bus controller 326 may be a computer bus used by the vehicle CPU to communicate with devices contained within the computer through physical connections such as cables or printed circuits. The vehicle CPU transmits various control signals to components and devices to transmit control signals to the CPU using the control bus. One of the main objectives of a bus is to minimize the lines needed for communication. The bus controller 326 may be bidirectional and assists the CPU in synchronizing control signals to internal devices and external components. It comprises interrupt lines, byte enables lines, read/write signals, and status lines. The micro-LED unit 328 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit 328 may be produced in a plurality of sizes to increase the width or length of the micro-LED unit 328. The sign markers 301 may be enhanced by using a micro-LED panel 328 through the rotating color module 320. The rotating color module 320 begins by continuously polling to receive sensor data from the sensors. For example, the sensors may be a charge-coupled device (CCD) camera, multispectral camera, laser, infrared sensor, radar sensor, etc., that have downstream processing to identify sign markers 301 in the path or in front of the vehicle. In some embodiments, the rotating color module 320 may use image recognition to identify the sign markers 301. The rotating color module 320 receives the sensor data from the sensors. For example, the sensors may be a charge-coupled device (CCD) camera, multispectral camera, laser, infrared sensor, radar sensor, etc., that have downstream processing to identify sign markers 301 in the path or in front of the vehicle. In some embodiments, the rotating color module 320 may use image recognition to identify the sign markers 301. The rotating color module 320 determines if there is an object through the collected sensor data. For example, if there is an object identified through the sensor data, the rotating color module may determine if the object is a sign marker 301. If it is determined that there is no object, the process returns to collecting sensor data. The rotating color module 320 determines if the object is a sign marker 301. For example, the rotating color module 320 may compare the identified object to a sign marker database which contains the various shapes, colors, etc., of the sign markers 301 to allow the rotating color module 320 to identify the object as a road marker through the shape of the object. If the object is a sign marker 301, the rotating color module 320 compares the sign marker 301 to a rules database. The rules database may contain a plurality of sign markers 301 and a corresponding rule or executable program that would be sent to the bus controller 326 to send the signal to the micro-LED panel 328 to produce a specific light to brighten the sign marker 301. For example, if the sign marker 301 identified was a directional sign marker 301, the corresponding rule or executable program may be for the micro-LED panel 328 to produce a green light to brighten the effects of the green sign marker 301. For example, since the sign marker 301 is green, the green light produced by the micro-LED panel 328 would reflect back the green color of the sign marker 301, and the white portion of the sign marker 301 would be reflected by the sign marker 301 displaying the sign marker 301 as a bright green and white sign marker 301. In some embodiments, the light produced by the micro-LED panel 328 may be a slightly altered light that contains more wavelengths for the color of the sign marker 301 that is detected. For example, light is made up of wavelengths of light, and each wavelength is a particular color. For example, if the sign marker 301 is green and white, the light produced by the micro-LED panel may be white, containing all wavelengths, with additional wavelengths that produce a green color. In some embodiments, the corresponding wavelength may be flashed or flickered on and off to still give the appearance of a white headlight to the naked eye but produces a brighter sign to the driver since there are more corresponding wavelengths of the color of the sign marker 301. The rotating color module 320 extracts the corresponding rule from the rules database. For example, the rules database may contain a plurality of sign markers 301 and a corresponding executable program that would be sent to the bus controller 326 to send the signal to the micro-LED panel 328 to produce a specific light to brighten the sign marker 301. The rotating color module 320 executes the extracted rule from the rules database. For example, the rotating color module 320 extracts the corresponding rule, or executable program. It executes the program by sending the appropriate signals to the bus controller 326 to illuminate the micro-LED panel 328 in the appropriate lighting, such as if a green and white sign marker 301 is identified then the extracted rule would be for the micro-LED panel 328 to produce a green light to brighten the sign marker 301.

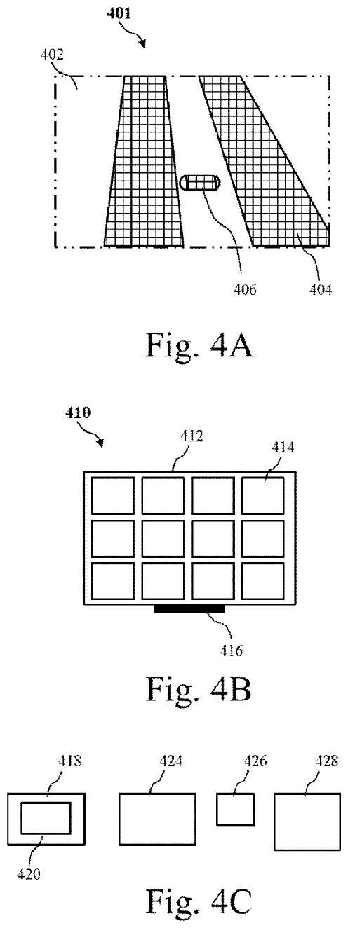

FIG. 4 illustrates an embodiment of using micro-LEDs in a headlight to enhance road reflectors. FIG. 4A displays a road reflector and road lines that may be enhanced by using micro-LEDs in a headlight. Road reflectors 401 may be reflective objects placed on the road between pavement stripes, solid pavement lines, and exit/entrance ramps to give drivers a better guide at night. Road reflectors 401 may be a road surface marking is any kind of device or material used on a road surface to convey official information. Road reflectors 401 may be a raised pavement marker, such as a road safety device. These devices are usually made with plastic, ceramic, thermoplastic paint, glass, or occasionally metal and come in various shapes and colors. The road 402 may be a wide way leading from one place to another, especially one with a specially prepared surface that vehicles can use. Road lane material 404 may be a kind of device or material that is used on a road surface to convey official information. The road lane material 404 may be road paint which contains pigment, a polymer resin, an acrylic, and water for the solvent, and as the water evaporates, the paint dries, and the polymer coalesces. Road reflectors 406 may be reflective objects placed on the road in between pavement stripes, solid pavement lines, and exit/entrance ramps to give drivers a better guide at night. Road reflectors 406 may be a road surface marking, which is any kind of device or material used on a road surface to convey official information. Road reflectors 406 may be a raised pavement marker, such as a road safety device. These devices are usually made with plastic, ceramic, thermoplastic paint, glass, or occasionally metal and come in various shapes and colors. FIG. 4B displays an embodiment of the micro-LED panel 410, which produces a plurality of colors to illuminate the road reflectors 401. The micro-LED panel 410 may be comprised of one or more tiles that contain multiple micro-LEDs. Multiple small micro-LED tiles can be integrated together into a larger flat plate. The micro-LED panel 410 may include a substrate 412, micro-LED unit 414, and a plurality of connectors 416. The micro-LED panel 410 allows for a micro-LED unit 414 to produce visual effects for a driver to act as a headlight or replace a vehicle's existing headlight, such as illuminating a driver's path while driving at night or during dark conditions. In some embodiments, the micro-LED unit 414 may be connected, bonded, adhered, etc., to a vehicle's headlight to produce light or illuminate the vehicle's path. The substrate 412 may be made of glass, silicon, plastics, or any other commonly used material. The substrate 412 may also have active electronic components such as but not limited to transistors, resistors, capacitors, or any other electronic component commonly used in a system substrate. In some cases, the substrate 412 may be a substrate 412 with electrical signal rows and columns. In one example, the substrate 412 may be a sapphire substrate with LED layers grown monolithically on top of it, and the substrate 412 may be a backplane with circuitry to derive micro-LED devices. In some embodiments, the substrate 412 may be a flexible or rigid substrate 412. The micro-LED unit 414 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit 414 may be produced in a plurality of sizes to increase the width or length of the micro-LED unit 414. The connectors 416 may be an electrochemical device used to create an electrical connection between the plurality of micro-LED tiles, which create the micro-LED unit 414. The connectors 416 may receive power, data signals, informational instructions, etc., from the ribbon connector to power and control the individual micro-LEDs in the micro-LED tiles that make up the micro-LED unit 414. FIG. 4C displays the components of the micro-LED headlight to produce a plurality of colors to illuminate the road reflectors 401. The components may include a memory 418, a rotating color module 420, a processor 424, a bus controller 426, and a micro-LED panel 428. The memory 418 may include, but is not limited to, fixed (hard) drives, magnetic tape, floppy diskettes, optical disks, Compact Disc Read-Only Memories (CD-ROMs), and magneto-optical disks, semiconductor memories, such as ROMs, Random Access Memories (RAMs), Programmable Read-Only Memories (PROMs), Erasable PROMs (EPROMs), Electrically Erasable PROMs (EEPROMs), flash memory, magnetic or optical cards, or another type of media/machine-readable medium suitable for storing electronic instructions. The memory 418 may comprise modules implemented as a program. The rotating color module 420 may include the executable program to produce the appropriate lighting conditions to brighten the road reflectors 401 using the micro-LED panel 428 by collecting data from a plurality of sensors, such as charge-coupled device (CCD) camera, multispectral camera, laser, infrared sensor, radar sensor, etc. that have downstream processing to identify road reflectors 401 in the path or in front of the vehicle. In some embodiments, the rotating color module 420 may use image recognition to identify the road reflectors 401. The rotating color module 420 is continuously receiving data from the sensors and determining if an object is a road reflector 401. If it is determined that the object is a road reflector 401, the rotating color module compares the road reflector 401 to a rules database. The rules database may contain a plurality of road reflectors 401 and a corresponding executable program that would be sent to the bus controller 426 to send the signal to the micro-LED panel 428 to produce a specific light to brighten the road reflector 401. The rotating color module 420 extracts the corresponding rule, or executable program, and executes the program by sending the appropriate signals to the bus controller 426 to illuminate the micro-LED panel 428 in the appropriate lighting. The processor 424 may be configured to decode and execute any instructions received from one or more electronic devices or server(s). The processor 424 may include one or more general-purpose processors (e.g., INTEL® or Advanced Micro Devices® (AMD) microprocessors) and/or one or more special purpose processors (e.g., digital signal processors or Xilinx® System On Chip (SOC) Field Programmable Gate Array (FPGA) processor). The processor 424 may be configured to execute one or more computer-readable program instructions, such as program instructions, to carry out any of the functions described in this description. The bus controller 426 may be a computer bus used by the vehicle CPU to communicate with devices within the computer through physical connections such as cables or printed circuits. The vehicle CPU transmits various control signals to components and devices to transmit control signals to the CPU using the control bus. One of the main objectives of a bus is to minimize the lines needed for communication. The bus controller 426 may be bidirectional and assists the CPU in synchronizing control signals to internal devices and external components. It comprises interrupt lines, byte enables lines, read/write signals, and status lines. The micro-LED unit 428 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit 428 may be produced in a plurality of sizes to increase the width or length of the micro-LED unit 428. The road reflectors 401 may be enhanced using a micro-LED panel 428 through the rotating color module 420. The rotating color module 420 begins by continuously polling to receive sensor data from the sensors. For example, the sensors may be a charge-coupled device (CCD) camera, multispectral camera, laser, infrared sensor, radar sensor, etc., that have downstream processing to identify road reflectors 401 in the path or in front of the vehicle. In some embodiments, the rotating color module 420 may use image recognition to identify the road reflectors 401. The rotating color module 420 receives the sensor data from the sensors. For example, the sensors may be a charge-coupled device (CCD) camera, multispectral camera, laser, infrared sensor, radar sensor, etc., that have downstream processing to identify road reflectors 401 in the path or in front of the vehicle. In some embodiments, the rotating color module 420 may use image recognition to identify the road reflectors 401. The rotating color module 420 determines if there is an object through the collected sensor data. For example, if an object is identified through the sensor data, the rotating color module may determine if the object is a road reflector 401. If it is determined that there is no object, the process returns to collecting sensor data. The rotating color module 420 determines if the object is a road reflector 401. For example, the rotating color module 420 may compare the identified object to a sign marker database which contains the various shapes, colors, etc., of the road reflectors 401 to allow the rotating color module 420 to identify the object as a road reflector 401 through the shape of the object. If the object is a road reflector 401, the rotating color module 420 compares the road reflector 401 to a rules database. The rules database may contain a plurality of road reflectors 401 and a corresponding rule or executable program that would be sent to the bus controller 426 to send the signal to the micro-LED panel 428 to produce a specific light to brighten the road reflector 401. For example, if the road reflector 401 identified was a lane road reflector 401, the corresponding rule or executable program may be for the micro-LED panel 428 to produce a yellow light to brighten the effects of the yellow road reflector 401. For example, since the road reflector 401 is yellow, the yellow light produced by the micro-LED panel 428 would reflect back the yellow color of the road reflector 401, and the white portion of the road reflector 401 would be reflected by the road reflector 401 displaying the road reflector 401 as a bright yellow road reflector 401. In some embodiments, the light produced by the micro-LED panel 428 may be a slightly altered light that contains more wavelengths for the color of the road reflector 401 that is detected. For example, light is made up of wavelengths of light, and each wavelength is a particular color. For example, if the road reflector 401 is yellow, the light produced by the micro-LED panel may be white, such as containing all wavelengths, with additional wavelengths that produce a yellow color. In some embodiments, the corresponding wavelength may be flashed or flickered on and off to still give the appearance of a white headlight to the naked eye but produces a brighter sign to the driver since there are more corresponding wavelengths of the color of the road reflector 401. The rotating color module 420 extracts the corresponding rule from the rules database. For example, the rules database may contain a plurality of road reflectors 401 and a corresponding executable program that would be sent to the bus controller 426 to send the signal to the micro-LED panel 428 to produce a specific light to brighten the road reflector 401. The rotating color module 420 executes the extracted rule from the rules database. For example, the rotating color module 420 extracts the corresponding rule, or executable program. It executes the program by sending the appropriate signals to the bus controller 426 to illuminate the micro-LED panel 428 in the appropriate lighting, such as if a yellow road reflector 401 is identified, then the extracted rule would be for the micro-LED panel 428 to produce a yellow light to brighten the road reflector 401.

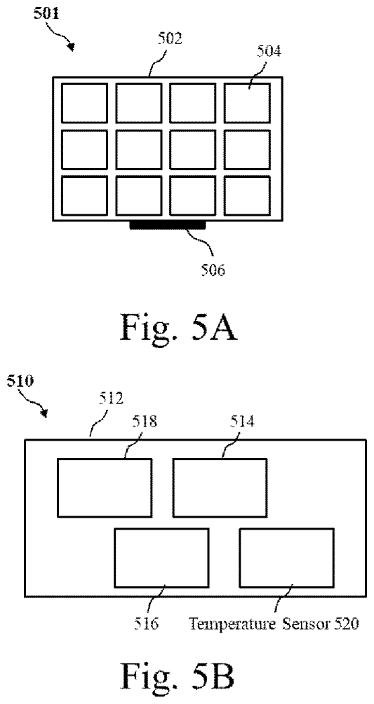

FIG. 5 illustrates an embodiment of using micro-LEDs in a headlight to enhance black ice detection. FIG. 5A displays an embodiment of the micro-LED panel 501, which produces a plurality of colors to illuminate the road to assist in detecting black ice. The micro-LED panel 501 may be comprised of one or more tiles that contain multiple micro-LEDs. Multiple small micro-LED tiles can be integrated together into a larger flat plate. The micro-LED panel 501 may include a substrate 502, micro-LED unit 504, and a plurality of connectors 506. The micro-LED panel 501 allows for a micro-LED unit 504 that can produce visual effects for a driver to act as a headlight or replace a vehicle's existing headlight, such as illuminating a driver's path while driving at night or during dark conditions. In some embodiments, the micro-LED unit 504 may be connected, bonded, adhered to, etc., to a vehicle's headlight to produce light or illuminate the vehicle's path. The substrate 502 may be made of glass, silicon, plastics, or any other commonly used material. The substrate 502 may also have active electronic components such as but not limited to transistors, resistors, capacitors, or any other electronic component commonly used in a system substrate. In some cases, the substrate 502 may be a substrate 502 with electrical signal rows and columns. In one example, the substrate 502 may be a sapphire substrate with LED layers grown monolithically on top of it, and the substrate 502 may be a backplane with circuitry to derive micro-LED devices. In some embodiments, the substrate 502 may be a flexible or rigid substrate 502. The micro-LED unit 504 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit 504 may be produced in a plurality of sizes to increase the width or length of the micro-LED unit 504. The connectors 506 may be an electrochemical device used to create an electrical connection between the plurality of micro-LED tiles, which creates the micro-LED unit 504. The connectors 506 may receive power, data signals, informational instructions, etc., from the ribbon connector to power and control the individual micro-LEDs in the micro-LED tiles that make up the micro-LED unit 504. FIG. 5B displays an embodiment of the black ice detector and the components of the system, such as a substrate 512, micro-LED panel 514, multispectral camera 516, and optical system 518. The substrate 512 may be made of glass, silicon, plastics, or any other commonly used material. The substrate 512 may also have active electronic components such as but not limited to transistors, resistors, capacitors, or any other electronic component commonly used in a system substrate. In some cases, the substrate 512 may be a substrate 512 with electrical signal rows and columns. In one example, the substrate 512 may be a sapphire substrate with LED layers grown monolithically on top of it, and the substrate 512 may be a backplane with circuitry to derive micro-LED devices. In some embodiments, the substrate 512 may be a flexible or rigid substrate 512. The micro-LED unit 514 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit 514 may be produced in a plurality of sizes to increase the width or length of the micro-LED unit 514. A multispectral camera 516 may capture image data within specific wavelength ranges across the electromagnetic spectrum. The wavelengths may be separated by filters or detected using instruments sensitive to particular wavelengths, including light from frequencies beyond the visible light range, i.e., infrared and ultraviolet. The optical system 518 may be a black ice detector system to distinguish water and ice from the road surface and each other by measurements of radiance at a few spectral bands. Photodetectors, thermopiles, and cameras with band-pass filters at appropriate wavelengths can be used to make these measurements. The optical system 518 may detect slippery conditions on roads and bridges. The detection of black ice can alert drivers as soon as slippery conditions are encountered ahead of the vehicle on roads, bridges, and parking lots. For example, the optical system 518 may be a system for detecting ice or large supercooled droplets within an area of interest, having a detection system measuring radiance or reflectance of the area of interest when exposed to shortwave infrared radiation having a wavelength in the range of about 2.05 μm to about 2.30 μm. The detection system measures the radiance or reflectance in a first band having a wavelength in the range of about 2.05 μm to about 2.15 μm and outputting a first band signal, and further measures the radiance or reflectance in a second band having a wavelength in the range of about 2.15 μm to about 2.30 μm and outputting a second band signal. A processing unit determines a ratio of the first band signal and the second band signal, compares the ratio to a predetermined critical ratio, and outputs a determination signal indicating the presence of ice or supercooled water droplets. The integrated black ice detector 510 may enhance the detection of black ice by using a micro-LED panel 514 through the black ice module. The black ice module begins by continuously polling to receive sensor data from the sensors. For example, the sensors may be optical system 518, multispectral camera 516, charge-coupled device (CCD) camera, laser, infrared sensor, radar sensor, etc., that have downstream processing to identify black ice in the path or in front of the vehicle. The black ice module receives the sensor data from the sensors. For example, the sensors may be optical system 518, multispectral camera 516, charge-coupled device (CCD) camera, laser, infrared sensor, radar sensor, etc., that have downstream processing to identify black ice in the path or in front of the vehicle. The black ice module determines if there is black ice. For example, the black ice module determines if there is black ice through the data collected from the sensor data collected. For example, the optical system 518 may be a black ice detector system to distinguish water and ice from the road surface and each other by measurements of radiance at a few spectral bands. Photodetectors, thermopiles, and cameras with band-pass filters at appropriate wavelengths can be used to make these measurements. The optical system 518 may detect slippery conditions on roads and bridges. The detection of black ice can alert drivers as soon as slippery conditions are encountered ahead of the vehicle on roads, bridges, and parking lots. For example, the optical system 518 may be a system for detecting ice or large supercooled droplets within an area of interest, having a detection system measuring radiance or reflectance of the area of interest when exposed to shortwave infrared radiation having a wavelength in the range of about 2.05 μm to about 2.30 μm. The detection system measures the radiance or reflectance in a first band having a wavelength in the range of about 2.05 μm to about 2.15 μm and outputting a first band signal, and further measures the radiance or reflectance in a second band having a wavelength in the range of about 2.15 μm to about 2.30 μm and outputting a second band signal. A processing unit determines a ratio of the first band signal and the second band signal, compares the ratio to a predetermined critical ratio, and outputs a determination signal indicating the presence of ice or supercooled water droplets. The black ice module extracts the corresponding rule from the rules database if black ice is detected by the optical system 518. For example, the corresponding rule may be to alert the driver of black ice on the road. In some embodiments, the rule may include adjusting the brightness of the light or the direction of the light produced by the micro-LED panel 514 to further assist the optical system 518 in detecting black ice. In some embodiments, the black ice detector 510 may include a temperature sensor 520 which may detect and measure temperature changes in an environment. The temperature sensor 520 may comprise a temperature-sensitive material, such as a thermistor, that changes its electrical resistance in response to changes in temperature. The temperature sensor 520 may also comprise a temperature-dependent voltage generator that produces a voltage proportional to the temperature. The temperature sensor 520 may be connected to a microcontroller or other processing unit that receives the sensor's output and converts it into a digital signal. The microcontroller may also be programmed to perform various temperature-related functions, such as temperature compensation, temperature monitoring, or temperature control. The data collected by the temperature sensor 520 may be used by the black ice detector 510 to determine the presence of black ice. In some embodiments, the rules database may contain rules corresponding to the data collected by the optical system 518 and the temperature sensor 520 to alert the driver of black ice on the road. For example, if black ice is detected by the optical system 518 and the temperature sensor 520 detects the temperature below 32 degrees then the corresponding rule may be to alert the driver of black ice, adjust the brightness of the light, direction of the light produced by the micro LED panel 514 to further assist the optical system 518 in detecting black ice.

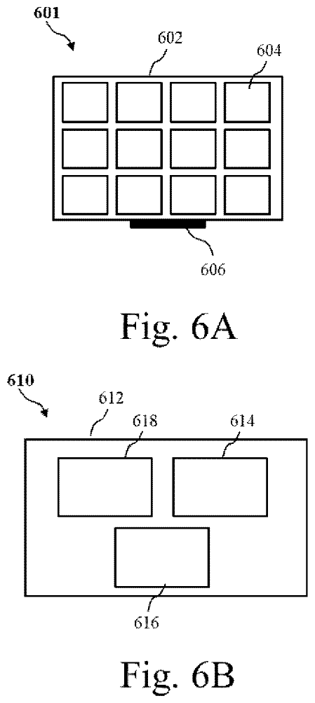

FIG. 6 illustrates an embodiment of using micro-LEDs in a headlight to enhance the interaction with oncoming traffic. FIG. 6A displays an embodiment of the micro-LED panel 601, which produces the plurality of colors to illuminate the road and adjust the intensity based on oncoming traffic. The micro-LED panel 601 may be comprised of one or more tiles that contain multiple micro-LEDs. Multiple small micro-LED tiles can be integrated together into a larger flat plate. The micro-LED panel 601 may include a substrate 602, micro-LED unit 604, and a plurality of connectors 606. The micro-LED panel 601 allows for a micro-LED unit 604 that can produce visual effects for a driver to act as a headlight or replace a vehicle's existing headlight, such as illuminating a driver's path while driving at night or during dark conditions. In some embodiments, the micro-LED unit 604 may be connected, bonded, adhered to, etc., to a vehicle's headlight to produce light or illuminate the vehicle's path. The substrate 602 may be made of glass, silicon, plastics, or any other commonly used material. The substrate 602 may also have active electronic components such as but not limited to transistors, resistors, capacitors, or any other electronic component commonly used in a system substrate. In some cases, the substrate 602 may be a substrate 602 with electrical signal rows and columns. In one example, the substrate 602 may be a sapphire substrate with LED layers grown monolithically on top of it, and the substrate 602 may be a backplane with circuitry to derive micro-LED devices. In some embodiments, the substrate 602 may be a flexible or rigid substrate 602. The micro-LED unit 604 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit 604 may be produced in a plurality of sizes to increase the width or length of the micro-LED unit 604. The connectors 606 may be an electrochemical device used to create an electrical connection between the plurality of micro-LED tiles, which creates the micro-LED unit 604. The connectors 606 may receive power, data signals, informational instructions, etc., from the ribbon connector to power and control the individual micro-LEDs in the micro-LED tiles that make up the micro-LED unit 604. FIG. 6B displays an embodiment of an oncoming traffic detector and the components of the system, such as a substrate 612, micro-LED panel 614, multispectral camera 616, and oncoming traffic controller 618. The substrate 612 may be made of glass, silicon, plastics, or any other commonly used material. The substrate 612 may also have active electronic components such as but not limited to transistors, resistors, capacitors, or any other electronic component commonly used in a system substrate. In some cases, the substrate 612 may be a substrate 612 with electrical signal rows and columns. In one example, the substrate 612 may be a sapphire substrate with LED layers grown monolithically on top of it, and the substrate 612 may be a backplane with circuitry to derive micro-LED devices. In some embodiments, the substrate 612 may be a flexible or rigid substrate 612. The micro-LED unit 614 contains a plurality of miniature LED (light emitting diodes) arrays, with each micro-LED functioning as a pixel and can be driven to emit light. Micro-LEDs comprise several microscopic LEDs, which self-illuminate per display pixel. Micro-LED is a modular technology. For example, panels are made up of a series of tiny red, green, and blue LEDs and are connected together to make one larger whole. In some embodiments, the micro-LED unit 614 may be produced in a plurality of sizes to increase the width or length of the micro-LED unit 614. A multispectral camera 616 may capture image data within specific wavelength ranges across the electromagnetic spectrum. The wavelengths may be separated by filters or detected using instruments sensitive to particular wavelengths, including light from frequencies beyond the visible light range, i.e., infrared and ultraviolet. The oncoming traffic controller 618 may detect oncoming traffic with the aid of a camera, in particular, a CCD camera having downstream image processing software and/or a laser, infrared, and/or radar sensor. These sensors detect whether another vehicle is on the road, such as approaching or positioned in front of the vehicle, concerning the detecting vehicle. A charge-coupled device (CCD) is a light-sensitive integrated circuit that captures images by converting photons to electrons. A CCD sensor breaks the image elements into pixels. Each pixel is converted into an electrical charge whose intensity is related to the intensity of light captured by that pixel. The integrated oncoming traffic detector 610 may adjust the intensity of the micro-LED panel 614 through the traffic module. The traffic module begins by continuously polling to receive sensor data from the sensors. For example, the sensors may be oncoming traffic controller 618, camera 616, charge-coupled device (CCD) laser, infrared sensor, radar sensor, etc., that have downstream processing to identify black ice in the path or in front of the vehicle. The traffic module receives the sensor data from the sensors. For example, the sensors may be oncoming traffic controller 618, camera 616, charge-coupled device (CCD) laser, infrared sensor, radar sensor, etc., that have downstream processing to identify black ice in the path or in front of the vehicle. The traffic module determines if there is traffic approaching the vehicle. For example, the oncoming traffic controller 618 may detect oncoming traffic with the aid of a camera, in particular, a CCD camera having downstream image processing software and/or a laser, infrared, and/or radar sensor. These sensors detect whether another vehicle is on the road, such as approaching or positioned in front of the vehicle, concerning the detecting vehicle. A charge-coupled device (CCD) is a light-sensitive integrated circuit that captures images by converting photons to electrons. A CCD sensor breaks the image elements into pixels. Each pixel is converted into an electrical charge whose intensity is related to the intensity of light captured by that pixel. The traffic module extracts the corresponding rule from the rules database if oncoming traffic is detected by the oncoming traffic controller 618. For example, the corresponding rule may be to adjust the insanity of the light produced by the micro-LED panel 614, such as turning off the high beam headlights, dimming the headlights, etc. In some embodiments, the traffic and black ice modules may be continuously running to assist the driver. In some embodiments, the rotating color module may be continuously running to detect and adjust the lights produced by the micro-LED panel 614 for road markers, sign markers, and road reflectors. For example, the rotating color module begins by continuously polling to receive sensor data from the sensors. For example, the sensors may be an optical system, oncoming traffic controller, charge-coupled device (CCD) camera, multispectral camera, laser, infrared sensor, radar sensor, etc., that have downstream processing to identify road markers, sign markers, road reflectors, black ice and oncoming traffic in the path or in front of the vehicle. In some embodiments, the rotating color module may use image recognition to identify road markers, sign markers, road reflectors, black ice, and oncoming traffic. The rotating color module receives the sensor data from the sensors. For example, the sensors may be an optical system, oncoming traffic controller, charge-coupled device (CCD) camera, multispectral camera, laser, infrared sensor, radar sensor, etc., that have downstream processing to identify road markers, sign markers, road reflectors, black ice and oncoming traffic in the path or in front of the vehicle. In some embodiments, the rotating color module may use image recognition to identify road markers, sign markers, road reflectors, black ice, and oncoming traffic. The rotating color module determines if there is an object through the collected sensor data. For example, if an object is identified through the sensor data, the rotating color module may determine if the object is a road marker, sign marker, road reflector, black ice, and oncoming traffic. If it is determined that there is no object, the process returns to collecting sensor data. The rotating color module determines if the object is a road marker, sign marker, road reflector, black ice, and oncoming traffic. For example, the rotating color module may compare the identified object to a database that contains the various shapes, colors, etc., of the road markers, sign markers, road reflectors, black ice, and oncoming traffic to allow the rotating color module to identify the object as a road marker, sign markers, road reflectors, black ice, and oncoming traffic through the shape of the object. If the object is a road marker, sign markers, road reflectors, black ice, and oncoming traffic, the rotating color module compares the road marker, sign markers, road reflectors, black ice, and oncoming traffic to a rules database. The rules database may contain a plurality of road markers, sign markers, road reflectors, etc., and a corresponding rule or executable program that would be sent to the bus controller to send the signal to the micro-LED panel 228 to produce a specific light to brighten the road marker, sign markers, road reflectors, make it easier to detect black ice or decrease the intensity of the lights for oncoming traffic. For example, if a road marker identified as an orange and black road marker, the corresponding rule or executable program may be for the micro-LED panel to produce an orange light to brighten the effects of the orange and black road marker. For example, since the road marker is orange and black, the orange light produced by the micro-LED panel would reflect back the orange color of the road marker, and the black portion of the road marker would be absorbed by the road marker displaying the road marker as a bright orange and black road marker. For example, if a sign marker identified was a directional sign marker, the corresponding rule or executable program may be for the micro-LED panel to produce a green light to brighten the effects of the green sign marker. For example, since the sign marker is green, the green light produced by the micro-LED panel would reflect back the green color of the sign marker, and the white portion of the sign marker would be reflected by the sign marker displaying the sign marker as a bright green and white sign marker. For example, if a road reflector is identified as a lane road reflector, the corresponding rule or executable program may be for the micro-LED panel to produce a yellow light to brighten the effects of the yellow road reflector. For example, since the road reflector is yellow, the yellow light produced by the micro-LED panel would reflect back the yellow color of the road reflector, and the white portion of the road reflector would be reflected by the road reflector displaying the road reflector as a bright yellow road reflector. In some embodiments, the light produced by the micro-LED panel may be a slightly altered light that contains more wavelengths for the color of the road marker, sign marker, or road reflector that is detected. For example, light is made up of wavelengths of light, and each wavelength is a particular color. For example, if the road marker is orange and black, the light produced by the micro-LED panel may be white, such as containing all wavelengths, with additional wavelengths that produce an orange color. In some embodiments, the corresponding wavelength may be flashed or flickered on and off to still give the appearance of a white headlight to the naked eye but produces a brighter sign to the driver since there are more corresponding wavelengths of the color of the road marker, sign marker, or road reflector. The rotating color module extracts the corresponding rule from the rules database. For example, the rules database may contain a plurality of road markers, sign markers, road reflectors, black ice, and oncoming traffic and a corresponding executable program that would be sent to the bus controller to send the signal to the micro-LED panel to produce a specific light to brighten the road marker, sign marker, road reflector, make it easier to detect black ice or dim the headlights for oncoming traffic. The rotating color module 220 executes the extracted rule from the rules database. For example, the rotating color module extracts the corresponding rule or executable program. It executes the program by sending the appropriate signals to the bus controller to illuminate the micro-LED panel in the appropriate lighting, such as if an orange and black road marker is identified, then the extracted rule would be for the micro-LED panel to produce an orange light to brighten the road marker.

The functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

1. A method of improving a driving visibility, the method comprising:
having an intelligent micro-LED headlight comprising a micro-LED panel comprised of a plurality of micro-LEDs, a substrate to which the micro-LED tile is bound, a connector which allows electronics of the micro-LED panel to integrate with a vehicle and a plurality of sensors, wherein, the sensors collect data of a vehicle's surroundings, the intelligent micro-LED headlight determines if there is an object, if there is an object, the intelligent micro-LED headlight determines if the object is a road marker, sign marker, road reflector, black ice or oncoming traffic, and compares the identified object to a rules database, extracts the corresponding rule, and adjusts, changes, or alters a light produced by the intelligent micro-LED headlight to improve the driving visibility.

2. The method of claim 1, wherein the light produced by the micro-LED panel is white light to reflect back an orange and black sign, an orange or a red and black sign to the driver.

3. The method of claim 1, wherein deep orange and black road markers are detected by a rotating color module and are displayed to the driver in a deep orange light produced by the micro-LED panel to brighten effects of a deep orange and black road marker.

4. The method of claim 1, wherein white and black road markers are detected by the rotating color module and are displayed to the driver in a white light produced by the micro-LED panel to brighten effects of a white and black road marker.

5. The method of claim 1, wherein, the light produced by the micro-LED panel is a plurality of light colors, such as reds, blues, or greens to reflect back the white and black sign to the driver.

6. The method of claim 1, wherein the micro-LED panel allows a micro-LED unit to produce visual effects for a driver to act as a headlight or replace a vehicle's existing headlight, such as illuminating a driver's path while driving at night or during dark conditions.

7. The method of claim 1, wherein the micro-LED unit is connected, bonded or adhered to a vehicle's headlight to produce a light or illuminate a vehicle's path.

8. The method of claim 1, wherein the substrate is made of glass, silicon, or plastics wherein further, the rigid substrate also has active electronic components such as but not limited to transistors, resistors, capacitors, or any other electronic component commonly used in a system substrate.

9. The method of claim 8, wherein the substrate is with electrical signal rows and columns.

10. The method of claim 8, wherein the substrate is a sapphire substrate with LED layers grown monolithically on top of it, and the substrate is a backplane with a circuitry to derive micro-LED devices.

11. The method of claim 8, wherein the substrate is either a flexible or a rigid substrate.
